(19) United States
(12) Patent Application Publication
(10) Pub. No.: US 2009/0166061 A1
(43) Pub. Date: Jul. 2, 2009

(54) PCB strip, PCB strip assembly device using the PCB strip, a method of using the PCB strip assembly device, and a method of fabricating a PCB strip

(76) Inventors: Cheol-Joon Yoo, Yeongtong-gu (KR); Tae-Sung Park, Cheonan-si (KR)

Correspondence Address: HARNESS, DICKEY & PIERCE, P.L.C., P.O. BOX 8910, RESTON, VA, 20195, US

(21) Appl. No.: 12/318,372

(22) Filed: Dec. 29, 2008

(30) Foreign Application Priority Data
Dec. 27, 2007 (KR) 10-2007-0138405

(51) Int. Cl. H05K 1/00; H05K 3/00

(52) U.S. Cl. 174/250; 29/829

(57) ABSTRACT

A PCB strip, a PCB strip assembly device, and methods of fabricating a PCB strip and using a PCB strip assembly device are provided. According to example embodiments, a PCB strip may include a PCB main body including a working area based on a process execution unit, wherein the working area may be divided into a first working area and a second working area and a plurality of units on the working area arrayed with a given interval in at least a width direction of the PCB main body, wherein the plurality of units may be arrayed on the first working area and the second working area and units on the first working area may be symmetric to units on the second working area with respect to a point of symmetry at a center of width of the working area.

### CROSS-REFERENCE TO RELATED APPLICATIONS

This application claims priority under 35 U.S.C. §119 to Korean Patent Application 10-2007-0138405, filed on Dec. 27, 2007, in the Korean Intellectual Property Office (KIPO), the entire contents of which are herein incorporated by reference.

### BACKGROUND

1. Field

Example embodiments relate to a printed circuit board (PCB), and more particularly, to a PCB strip, a PCB strip assembly device, a method of using the PCB strip assembly device, and a method of fabricating a PCB.

2. Description of the Related Art

A COB (Chip On Board) type semiconductor package may be manufactured by mounting a semiconductor chip on a PCB frame and electrically connecting the semiconductor chip to a circuit pattern formed in the PCB frame. The resulting structure may be encapsulated with mold resin. Such a scheme may be applied to an IC card. The PCB frame may be formed as a strip structure (a PCB strip) upon which a plurality of chips may be mounted so as to improve a throughput of processes in producing semiconductor packages.

A PCB strip may be formed by attaching the input/output pads of a semiconductor chip to a circuit pattern in the PCB. The circuit pattern may be formed by various processes, e.g., photo etching and thin film plating. A PCB strip may realize a circuit pattern corresponding to a high density semiconductor chip, e.g., an IC or LSI, and thus may be applied to Ball Grid Array Packages, Pin Grid Array Packages, and/or Chip Size Packages.

FIG. 1 is a plan view illustrating a conventional PCB strip 100. As shown in FIG. 1, a PCB strip 100 may be rectangular. On the surface of the PCB 100, chip mounting parts 110, e.g., circuit patterns for attaching semiconductor chips, may be arrayed with a uniform interval. In an upper part of the PCB 100, indication marks 130 may store information of the chip mounting part 110 and may be formed with a given interval, together with alignment holes 120. In a lower part opposite to that, indication marks 130 and alignment holes 120 of the same shape as the upper part thereof may be formed. In the alternative, a mold gate 140 as an injection passage of mold may be formed.

The alignment holes 120, the indication marks 130, and the mold gate 140, in the upper and lower parts of the PCB 100, may correspond to a non-working area of the PCB 100. The working area may be that part of the PCB 100 on which the chip mounting parts 110 are formed. When the mounting usability of a chip in the PCB is lowered, a PCB package manufacture cost may increase.

The size of the PCB panel used for manufacturing a PCB strip may be determined by a given standard. FIG. 2 is a plan view illustrating a structure of PCB strip for a conventional PCB. As shown in FIG. 2, twelve PCB strips 200 may be formed in two columns on one PCB 100. The number of PCB strips 200 may be reduced to six if the PCB strips 200 were extended in a width direction resulting in reduced costs associated with the manufacture of the PCB 100.

However, creating relatively long PCB strips may result in serious reliability problems. For example, a specific unit may be adapted for the large area of the PCB strip 200. Further, when the area becomes relatively large, a transfer distance for a robot lengthens, causing a working time delay for the unit and a drop in a drive rate. Furthermore, the quality of product may become compromised due to a lowered preciseness of work when the working distance becomes relatively long.

### SUMMARY

Example embodiments provide a PCB strip capable of substantially increasing space efficiency of respective units in respective working areas, by extending an area in a width direction, forming a working area based on a process execution unit as first and second working areas on the basis of a middle portion of the width direction, and by forming units on the working areas in a mutual point-symmetry.

According to example embodiments, a PCB strip may include a PCB main body including a working area based on a process execution unit, wherein the working area may be divided into a first working area and a second working area, and a plurality of units on the working area arrayed with a given interval in at least a width direction of the PCB main body, wherein the plurality of units may be arrayed on the first working area and the second working area and units on the first working area may be symmetric to units on the second working area with respect to a point of symmetry at a center of width of the working area.

According to example embodiments, a PCB strip assembly device may include a PCB main body including a working area based on a process execution unit, wherein the working area may be divided into a first working area and a second working area, a plurality of units on the working area arrayed with a given interval in at least a width direction of the PCB main body, wherein the plurality of units may be arrayed on the first working area and the second working area and units on the first working area may be symmetric to units on the second working area with respect to a point of symmetry at a center of width of the working area, a guide rail configured to support both end parts of the PCB strip from a lower part thereof, and configured to perform a loading and unloading operation into a process execution position, and a PCB stage configured to lift the PCB strip to a given or predetermined height, rotate the PCB strip, and drop the PCB strip so that a process for the second working area may be performed.

According to example embodiments, a method of using a PCB strip assembly may include providing at least one PCB strip, wherein the PCB strip may include a PCB main body including a working area based on a process execution unit, wherein the working area may be divided into a first working area and a second working area, a plurality of units on the working area arrayed with a given interval in at least a width direction of the PCB main body, wherein the plurality of units may be arrayed on the first working area and the second working area and units on the first working area may be symmetric to units on the second working area with respect to a point of symmetry at a center of width of the working area, mounting the at least one PCB strip in a loader, putting the at least one PCB strip on a guide rail from the loader part and transferring the at least one PCB strip to a process execution position, performing a process for the first working area of the at least one PCB strip in the process execution position, elevating and rotating a PCB stage when the process for the first working area of the at least one PCB strip is completed so that the at least one PCB rotates about 180 degrees, performing a process for the second working area of the rotated at least one PCB strip, and unloading the at least one PCB strip completed in the execution of the process for the first and second working areas from an unloader part.

According to example embodiments, a method of fabricating a PCB strip may include providing a PCB main body including a working area based on a process execution unit, wherein the working area may be divided into a first working area and a second working area, and providing a plurality of units on the working area arrayed with a given interval in at least a width direction of the PCB main body, wherein the plurality of units may be arrayed on the first working area and the second working area and units on the first working area may be symmetric to units on the second working area with respect to a point of symmetry at a center of width of the working area.

### BRIEF DESCRIPTION OF THE DRAWINGS

Example embodiments will be more clearly understood from the following detailed description taken in conjunction with the accompanying drawings. FIGS. 1-2 illustrate conventional art. FIGS. 3-5 represent non-limiting, example embodiments as described herein.

FIG. 1 is a plan view illustrating a PCB strip according to a conventional art;

FIG. 2 is a plan view illustrating a structure of PCB strip obtained in a conventional PCB;

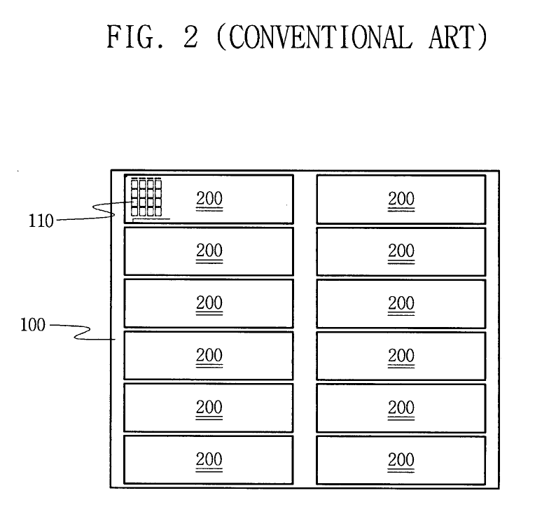

FIG. 3 is a plan view illustrating a PCB strip according to example embodiments;

FIG. 4 is a plan view schematically illustrating a structure of PCB strip assembly device according to example embodiments; and

FIG. 5 is a plan view schematically illustrating the configuration applied to change a working area of PCB to undergo an execution of process by rotating a PCB strip according to example embodiments.

### DETAILED DESCRIPTION OF THE EMBODIMENTS

Example embodiments will now be described more fully with reference to the accompanying drawings, in which example embodiments are shown. Example embodiments may, however, be embodied in different forms and should not be construed as limited to the embodiments set forth herein. Rather, these embodiments are provided so that this disclosure will be thorough and complete, and will fully convey the scope of example embodiments to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any an all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

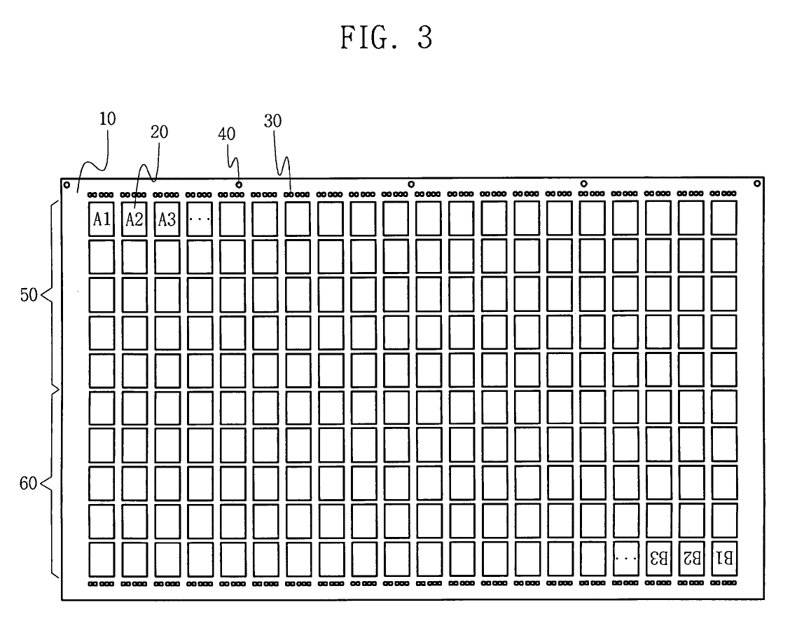

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments. Example embodiments now will be described more fully hereinafter with reference to FIGS. 3 to 5, in which example embodiments are shown.

FIG. 3 is a plan view illustrating a PCB strip according to example embodiments. A PCB strip may include a plurality of units 20 uniformly arrayed on a surface of a PCB main body 10. The area on the surface of the PCB main body 10 upon which the plurality of units 20 are arrayed is a working area. The PCB main body may have a rectangular shape based on a given or predetermined size.

Each unit 20 may include a chip mounting part having a circuit pattern. Information for respective units 20 may be represented in indication marks 30 along one side outer edge in a length direction of the PCB main body 10, and in such outer edge part, alignment holes 40 may be formed with a given interval in a length direction.

In another side outer edge part, corresponding to the one side outer edge part on which the indication marks 30 are formed in the length direction of the PCB main body 10, indication marks 30 having information of the units 20 may be formed in the same scheme as the one side outer edge part according to the structure of the packaging mold. In the alternative, a mold gate as an injection passage of mold may be formed.

As illustrated in FIG. 3, the size of PCB main body 10 may be extended twice in a width direction. The working area, upon which a plurality of units are arrayed, may be based on a process execution unit and may be divided into a first working area 50 and a second working area 60.

In the conventional art only one working area is formed, but in example embodiments, the area of PCB main body 10 may be extended twice and the same two working areas may be formed in one PCB main body 10. The respective units 20, formed in respective working areas, may be arrayed in a point symmetry. For example, units A1, A2, and A3 in the first working area 50 of FIG. 3 may correspond to units B1, B2, and B3 in the second working area 60. As illustrated, units A1, A2, and A3 may be point symmetric to units B1, B2, and B3.

For reference, a working area in a PCB main body may indicate an area of width and length to perform a work per PCB in a process execution position of the system, and the PCB strip may have a size based on a unit of such working area.

As described above, two working areas may be formed in a width direction in the PCB main body 10, and respective units 20 in two working areas may be formed in a point symmetry.

In extending twice in a width direction the size of the PCB main body 10 the formation space of unit 20 may become wide compared with one working area formed in one PCB main body.

According to a conventional art, non-working areas may be formed on both sides of the PCB main body, in the width direction. When two conventional PCB main bodies are connected, the two non-working areas may be continuously arrayed in the mutually coupled portion. However, according to example embodiments, the size of PCB main body may be extended twice and a non-working area on a connection portion between conventional PCB main bodies may be omitted, thus space to form units thereon may increase.

Accordingly, in the PCB strip according to example embodiments, the size may be extended in a width direction, and first and second working areas 50 and 60 may be formed in a line, thereby omitting a non-working area between these working areas, so that more units 20 may be formed on each working area. As described above, in example embodiments, two working areas may be formed on a large and extended area and units 20 of the two working areas may be formed in a point symmetry.

A given number of the PCB strips according to example embodiments may be transferred by a transfer unit, e.g., a specific cassette, in a movement between pieces of equipment. To each piece of equipment, the PCB strips may be supplied, one by one, by a robot. In the PCB strip, an assembly process, e.g., a die attach, wire bonding, and a packaging, according to a characteristic of the units, may be performed.

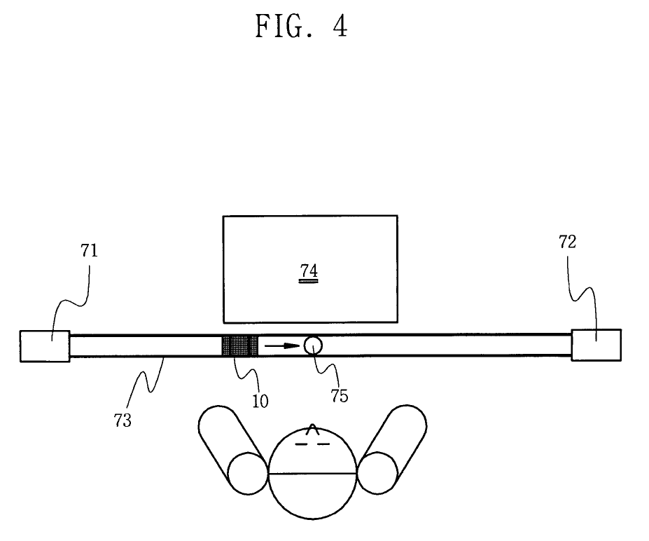

During assembly, specific processes may be performed by a robot, and the process equipment may be installed in a direction corresponding to an engineer's management area on a guide rail. FIG. 4 is a plan view schematically illustrating a PCB strip assembly device according to example embodiments.

In the PCB strip assembly device according to example embodiments, a guide rail 73 may be installed between a loader part 71 and an unloader part 72, and a PCB strip 10 may be transferred in the guide rail 73. At a process execution position along the guide rail 73, a specific separate process, e.g., die attaching or wire bonding or packaging, may be performed by process equipment 74.

The process equipment 74 may be adapted only in one side of the guide rail 73, and another side thereof may be a working space for an engineer. In such configuration, the width of the guide rail 73, individually supporting the low face of both end parts of the PCB strip, may be controlled to account for the width of the PCB strip. The width control of the guide rail 73 may be adjusted by a simple manipulation without replacing the unit.

In the PCB strip assembly device according to example embodiments, a PCB stage 75 may be installed at a position of the guide rail 73 where a specific process of the process equipment 74 may be performed. The PCB stage 75 may be configured to raise and/or rotate the PCB strip from the guide rail 73 a given or predetermined height and/or configured to rotate the PCB strip a given or predetermined degree, e.g., about 180°. The PCB stage 75 may be formed in a given size to mount the PCB strip on an upper part thereof. A driving unit (not shown) for an elevation and rotation may be provided below the PCB stage 75.

Process equipment 74 may be arrayed in series, for example, the same two process equipment 74 may be coupled in series in one system, and one process equipment 74 may perform a process for a first working area 50, and other process equipment 74 may perform a process for a second working area 60. The PCB stage 75 may be adapted in any one of the process equipment 74.

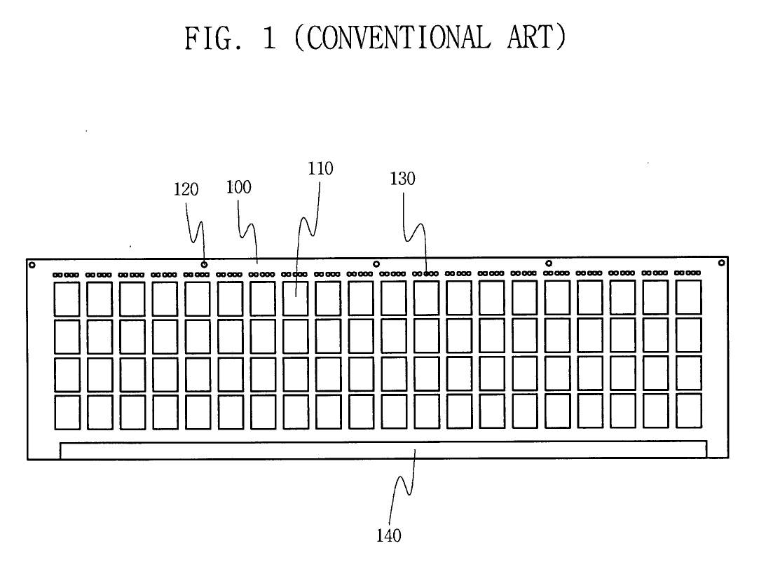

It may be beneficial to apply a compressed mold scheme to example embodiments rather than the mold scheme illustrated in FIG. 1. The mold scheme of FIG. 1 injects mold from a gate on one side of the PCB strip. Because the distance between the edges of the PCB strip in example embodiments is increased over the distance between the edges of the PCB strip in the conventional art, the increased distance may cause a deviation in the molding state thereby increasing process error. Because it may be beneficial to apply a compressed mold scheme to example embodiments, it may also be beneficial to have a non-working area with indication marks on both end parts of a width direction thereof.

As described above, the PCB strip according to example embodiments may be twice as wide as a conventional PCB strip, thus, the width of guide rail 73 for transferring the PCB strip of example embodiments may be changed appropriately for the new configuration. Also, in a middle position between the guide rails 73, a PCB stage 75 ascending/descending and rotatable may be adapted.

A specific process of the first working area, e.g., a die attach or wire bonding, may be performed in the PCB main body 10 at a process execution position of the process equipment 74, and the PCB stage 75 may raise the PCB main body 10 a predetermined or given height from the guide rail 73. The PCB main body may also be rotated by a given angle, e.g. about 180°.

The process equipment 74 may process the first working area 50 and the second working area 60. For example, when the process for the first working area 50 is completed, the PCB main body 10 may be raised a given or predetermined height and rotated about 180° so that the second working area 60 may be positioned in the process equipment 74 side.

The process execution may also occur in the PCB stage 75. The PCB strip may be induced into the process execution position of process equipment 74, and the PCB stage 75 may be raised by a given height so that the process may be performed in a state that the PCB strip is distant from the guide rail 73.

When the process execution for the first working area 50 of the PCB strip is completed, a process for the second working area 60 may be performed by rotating about 180° the guide rail 73. When processes for the second working area 60 are completed, the PCB stage 75 may be lowered intact or may be lowered again after rotating it by about 180°. When the PCB strip is mounted on the guide rail 73 through the lowered operation of the PCB stage 75, the PCB strip completed in the process may be transferred to the unloader part. In a specific respective equipment, two lines may be installed in series so that the processes for the first and second working areas 50 and 60 may be performed on different lines.

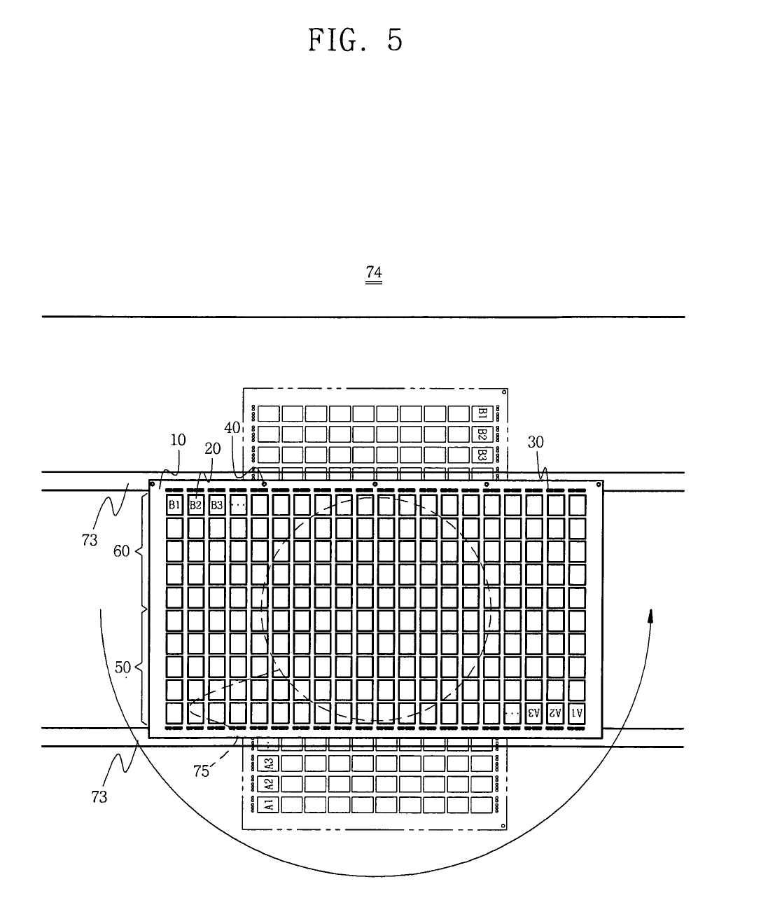

FIG. 5 is a plan view schematically illustrating a rotation of a PCB strip according to example embodiments. As shown, the PCB may be rotated to reposition the working areas of the PCB so that the different working areas may be processed by the process equipment 74. As shown in FIG. 5, a specific process for first working area 50 of PCB strip may be performed, and then the PCB stage 75 may rotate about 1800 so that the second working area 60 may be positioned at a process execution position of the process equipment 74.

Thus, a relatively larger area for a working area as a process execution unit may be obtained according to example embodiments, thereby simultaneously forming two working areas of first and second working areas 50 and 60 on the PCB strip and increasing space use efficiency through an increase of unit formation rate in the PCB main body 10.

In addition, according to example embodiments, an interval between guide rails 73 may be controlled and the PCB stage 75 ascendable/descendable and rotatable may be added, thereby increasing a process execution efficiency and productivity only through a relatively minimum equipment alteration. In particular, relatively more units may be adapted in one PCB main body 10, thereby substantially reducing a manufacturing cost of the PCB strip.

It will be apparent to those skilled in the art that modifications and variations can be made in example embodiments without deviating from the spirit or scope of example embodiments. Thus, it is intended that example embodiments cover any such modifications and variations provided they come within the scope of the appended claims and their equivalents. Accordingly, these and other changes and modifications are seen to be within the true spirit and scope of example embodiments as defined by the appended claims.

In the drawings and specification, there have been disclosed example embodiments and, although specific terms are employed, they are used in a generic and descriptive sense only and not for purposes of limitation, the scope of example embodiments being set forth in the following claims.

What is claimed is:

1. A PCB strip comprising:
a PCB main body including a working area based on a process execution unit, wherein the working area is divided into a first working area and a second working area;
a plurality of units on the working area arrayed with a given interval in at least a width direction of the PCB main body, wherein the plurality of units are arrayed on the first working area and the second working area and units on the first working area are symmetric to units on the second working area with respect to a point of symmetry at a center of width of the working area.

2. The PCB strip of claim 1, wherein the units include a chip mounting part having a circuit pattern.

3. The PCB strip of claim 1, wherein the PCB main body includes a non-working area in both outer edge end parts of width direction of the PCB main body.

4. The PCB strip of claim 3, wherein the non-working area includes indication marks storing unit information and alignment holes at a given interval.

5. A PCB strip assembly device, comprising:
the PCB strip of claim 1;
a guide rail configured to support both end parts of the PCB strip from a lower part thereof, and configured to perform a loading and unloading operation into a process execution position; and
a PCB stage configured to lift the PCB strip to a given height, rotate the PCB strip, and drop the PCB strip so that a process for the second working area is performed.

6. The PCB strip assembly device of claim 5, wherein the PCB stage is further configured to rotate the PCB strip by about 180 degrees.

7. The assembly device of claim 5, wherein in one side of the guide rail, a first process equipment for performing a process for the first working area of the PCB strip, and a second process equipment for performing a process for the second working area, are in series.

8. The assembly device of claim 7, wherein the PCB stage is configured to perform a rotation of about 180 degrees for one of the first and second process equipments.

9. A method of using a PCB strip assembly comprising:
providing at least one PCB strip, wherein the PCB strip includes a PCB main body including a working area based on a process execution unit, wherein the working area is divided into a first working area and a second working area and a plurality of units on the working area arrayed with a given interval in at least a width direction of the PCB main body, wherein the plurality of units are arrayed on the first working area and the second working area and units on the first working area are symmetric to units on the second working area with respect to a point of symmetry at a center of width of the working area;
mounting the at least one PCB strip in a loader;
putting the at least one PCB strip on a guide rail from the loader part and transferring the at least one PCB strip to a process execution position;
performing a process for the first working area of the at least one PCB strip in the process execution position;
elevating and rotating a PCB stage when the process for the first working area of the at least one PCB strip is completed so that the at least one PCB rotates about 180 degrees;
performing a process for the second working area of the rotated at least one PCB strip; and
unloading the at least one PCB strip completed in the execution of the process for the first and second working areas to an unloader part.

10. The method of claim 9, wherein the PCB stage raises the at least one PCB strip from the guide rail in a process execution position of the guide rail and loads it thereon, and a process for the first working area is performed.

11. The method of claim 9, wherein the PCB stage rotates the at least one PCB strip by about 180 degrees when a process for the second working area of the at least one PCB strip is completed, and then unloads the PCB strip into the unloader part.

12. The method of claim 9 wherein the at least one PCB strip is a plurality of PCB strips and the plurality of PCB strips are transferred from the loader to the guide rail one sheet by one sheet.

13. A method of fabricating a PCB strip comprising:
providing a PCB main body including a working area based on a process execution unit, wherein the working area is divided into a first working area and a second working area; and
providing a plurality of units on the working area arrayed with a given interval in at least a width direction of the PCB main body, wherein the plurality of units are arrayed on the first working area and the second working area and units on the first working area are symmetric to units on the second working area with respect to a point of symmetry at a center of width of the working area.

14. The PCB strip of claim 13, wherein the units include a chip mounting part having a circuit pattern.

15. The PCB strip of claim 13, wherein the PCB main body includes a non-working area in both outer edge end parts of width direction of the PCB main body.

16. The PCB strip of claim 15, wherein the non-working area includes indication marks storing unit information and alignment holes at an interval.
